(19) United States
(12) Patent Application Publication
(10) Pub. No.: US 2010/0091546 A1
(43) Pub. Date: Apr. 15, 2010

(54) HIGH DENSITY RECONFIGURABLE SPIN TORQUE NON-VOLATILE MEMORY

(75) Inventors: Hongyue Liu, Maple Grove, MN (US); Xuguang Wang, Eden Prairie, MN (US); Yong Lu, Rosemount, MN (US); Yiran Chen, Eden Prairie, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/251,788

(22) Filed: Oct. 15, 2008

(51) Int. Cl. G11C 17/02; G11C 11/409; G11C 11/02

(52) U.S. Cl. 365/97; 365/189.16; 365/171

(57) ABSTRACT

One time programmable memory units include a magnetic tunnel junction cell electrically coupled to a bit line and a word line. The magnetic tunnel junction cell is pre-programmed to a first resistance state, and is configured to switch only from the first resistance state to a second resistance state by passing a voltage across the magnetic tunnel junction cell. In some embodiments, a transistor is electrically coupled between the magnetic tunnel junction cell and the word line or the bit line. In other embodiments, a device having a rectifying switching characteristic, such as a diode or other non-ohmic device, is electrically coupled between the magnetic tunnel junction cell and the word line or the bit line. Methods of pre-programming the one time programmable memory units and reading and writing to the units are also disclosed.

### BACKGROUND

Fast growth of the pervasive computing and handheld/communication industry generates exploding demand for high capacity nonvolatile solid-state data storage devices.

There has been significant interest in one time programmable memory (OTP) recently. Such memory can be used in a wide variety of applications. For industry applications, OTP memory can be used to provide unique die/chip IDs and to set operating parameters such as clock multipliers and voltage levels for devices such as microprocessors. OTP memory may also be used to configure, customize, and repair a chip after testing (e.g., to repair a processor chip's cache memory array).

One time programmable memory also has many applications in consumer electronics as well, such as one time use digital film, low cost multimedia advertisement distribution, and gaming console cartridges. The boom of the high definition (HD) quality content opens an even larger market for OTP devices, as HD requires much higher density and faster writing speed due to the high bit rate.

Current OTP memory cells use either charge storage, which can be reconfigured but has only limited speed, or use fuse/antifuse approaches, which cannot be reconfigured. In addition, with all these conventional approaches, an OTP cell usually consists of multiple MOS devices, which occupy high area. It is highly desirable if OTP memory can be implemented in a more simple manner to achieve a higher density.

### BRIEF SUMMARY

The present disclosure relates to a spin torque based, ultra high density, one time programmable yet multi-time reconfigurable memory array architectures. Methods to program these memory arrays are also described. Such memories have high potential for ultra high density, low cost and high speed applications

Memory units of this disclosure include a magnetic tunnel junction cell electrically coupled to a bit line and a word line. The magnetic tunnel junction cell is pre-programmed to a first resistance state, and the cell is configured to switch only from that first resistance state to a second resistance state by passing a voltage across the magnetic tunnel junction cell. The magnetic tunnel junction cell does not switch back to the first resistance state from the second resistance state. In some embodiments, a transistor is electrically coupled between the magnetic tunnel junction cell and the word line or the bit line. In other embodiments, a diode is electrically coupled between the magnetic tunnel junction cell and the word line or the bit line. A voltage source provides the voltage across the magnetic tunnel junction cell that writes the low resistance state.

In one particular embodiment, this disclosure provides a one time programmable (OTP) memory unit that includes a magnetic tunnel junction cell configured to switch only from a first resistance state to a second resistance state by passing a voltage across the magnetic tunnel junction cell. The magnetic tunnel junction cell does not switch back to the first resistance state from the second resistance state. A non-ohmic device is electrically coupled between the magnetic tunnel junction cell and the connected word line or bit line. The memory unit includes a voltage source to provide the voltage that writes the low resistance state to the cell. The non-ohmic device can be a diode.

In another particular embodiment, this disclosure provides a method of pre-programming a magnetic tunnel junction cell. The method includes orienting the free layer magnetization orientation in relation to the pinned layer magnetization orientation of a magnetic tunnel junction cell by exposing the cell to an external magnet.

In yet another particular embodiment, this disclosure provides a method that includes writing to a one time programmable memory unit by switching the magnetic tunnel junction cell from a first resistance state to a second resistance state by passing a forward bias voltage through the magnetic tunnel junction cell, the voltage providing a current of no more than about 500 microAmps, or, no more than about 200 microAmps or about 100 microAmps. The forward bias voltage could pass through the magnetic tunnel junction cell and through a transistor, or, through the magnetic tunnel junction cell and through a diode.

Methods for reading the one time programmable memory unit and again reading the one time programmable memory unit are also disclosed.

### BRIEF DESCRIPTION OF THE DRAWINGS

The disclosure may be more completely understood in consideration of the following detailed description of various embodiments of the disclosure in connection with the accompanying drawings, in which:

FIG. 1A is a cross-sectional schematic diagram of an illustrative magnetic tunnel junction cell in a high resistance state; FIG. 1B is a cross-sectional schematic diagram of the magnetic tunnel junction cell in a low resistance state;

FIGS. 2A and 2B are schematic circuit diagrams of a memory unit utilizing a transistor with a magnetic tunnel junction cell;

FIGS. 3A and 3B are schematic circuit diagrams of a memory unit utilizing a diode with a magnetic tunnel junction cell; FIG. 3C is a perspective view schematic diagram of an illustrative memory unit;

FIG. 4 is a schematic circuit diagram of an illustrative memory array with the memory units of FIGS. 3A and 3C;

FIG. 5 is a flow chart illustrating a method for pre-programming a magnetic tunnel junction cell to a first resistance state; and

FIG. 6 is a flowchart illustrating a method of switching a magnetic tunnel junction cell from a first resistance state to a second resistance state.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

The present disclosure relates to spin torque (ST) based non-volatile memory. In particular, present disclosure relates to spin torque based, ultra high density, one time programmable (OTP) yet multi-time reconfigurable memory array architectures. A memory array of this disclosure includes memory units, which include a magnetic tunnel junction cell that can be programmed once, yet read multiple times. The magnetic tunnel junction cell is configured to be switchable only from a first resistance state to a second resistance state, and not switched back to the first state under normal use conditions. The memory unit includes either a transistor or device having a rectifying switching characteristic, such as a diode or other non-ohmic device, to limit the voltage bias to the forward direction.

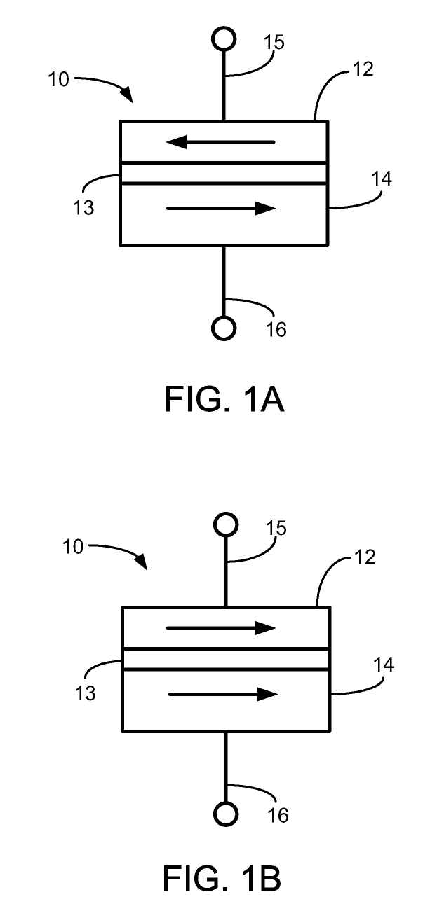

Spin torque (ST) non-volatile memory has been one attractive candidate for next generation flash memory applications due to its faster speed and high reliability. FIGS. 1A and 1B are a cross-sectional schematic diagram of an illustrative magnetic tunnel junction cell 10; in FIG. 1A, cell 10 is in a first, high resistance state, with the magnetization orientations anti-parallel and in FIG. 1B, cell 10 is in a second, low resistance state, with the magnetization orientations parallel.

Magnetic tunnel junction cell 10 includes a ferromagnetic free layer 12 and a ferromagnetic reference (i.e., pinned) layer 14. Ferromagnetic free layer 12 and ferromagnetic pinned layer 14 are separated by an oxide barrier layer 13 or non-magnetic tunnel barrier. Ferromagnetic layers 12, 14 may be made of any useful ferromagnetic (FM) material such as, for example, Fe, Co or Ni and alloys thereof, such as NiFe and CoFe. Ternary alloys, such as CoFeB, may be particularly useful because of their lower moment and high polarization ratio, which are desirable for the spin-current switch. Either or both of free layer 12 and pinned layer 16 may be either a single layer or an unbalanced synthetic antiferromagnetic (SAF) coupled structure, i.e., two ferromagnetic sublayers separated by a metallic spacer, such as Ru or Cu, with the magnetization orientations of the sublayers in opposite directions to provide a net magnetization. Barrier layer 13 may be made of an electrically insulating material such as, for example an oxide material (e.g., Al₂O₃, TiO or MgO). Other suitable materials may also be used. Barrier layer 13 could optionally be patterned with free layer 12 or with pinned layer 14, depending on process feasibility and device reliability.

The following are various specific examples of magnetic tunnel junction cells 10. In some embodiments of magnetic tunnel junction cell 10, oxide barrier layer 13 includes Ta₂O₅ (for example, at a thickness of about 0.5 to 1 nanometer) and ferromagnetic free layer 12 and a ferromagnetic pinned layer 14 include NiFe, CoFe, or Co. In other embodiments of magnetic tunnel junction cell 10, barrier layer 13 includes GaAs (for example, at a thickness of about 5 to 15 nanometers) and ferromagnetic free layer 12 and ferromagnetic pinned layer 14 include Fe. In yet other embodiments of magnetic tunnel junction cell 10, barrier layer 13 includes Al₂O₃ (for example, a few nanometers thick) and ferromagnetic free layer 12 and ferromagnetic pinned layer 14 include NiFe, CoFe, or Co.

A first electrode 15 is in electrical contact with ferromagnetic free layer 12 and a second electrode 16 is in electrical contact with ferromagnetic pinned layer 14. Electrodes 15, 16 electrically connect ferromagnetic layers 12, 14 to a control circuit providing read and write currents through layers 12, 14. The resistance across magnetic tunnel junction cell 10 is determined by the relative orientation of the magnetization vectors or magnetization orientations of ferromagnetic layers 12, 14. The magnetization direction of ferromagnetic pinned layer 14 is pinned in a predetermined direction while the magnetization direction of ferromagnetic free layer 12 is free to rotate under the influence of spin torque. Pinning of ferromagnetic pinned layer 14 may be achieved through, e.g., the use of exchange bias with an antiferromagnetically ordered material such as PtMn, IrMn, and others.

FIG. 1A illustrates magnetic tunnel junction cell 10 in the high resistance state where the magnetization orientation of ferromagnetic free layer 12 is anti-parallel and in the opposite direction of the magnetization orientation of ferromagnetic pinned layer 14. This is termed the high resistance state or “1” data state. FIG. 1B illustrates magnetic tunnel junction cell 10 in the low resistance state where the magnetization orientation of ferromagnetic free layer 12 is parallel and in the same direction of the magnetization orientation of ferromagnetic pinned layer 14. This is termed the low resistance state or “0” data state.

Switching the resistance state and hence the data state of magnetic tunnel junction cell 10 via spin-transfer occurs when a current, passing through a magnetic layer of magnetic tunnel junction cell 10, becomes spin polarized and imparts a spin torque on free layer 12 of magnetic tunnel junction cell 10. When a sufficient spin torque is applied to free layer 12, the magnetization orientation of free layer 12 can be switched between two opposite directions and accordingly, magnetic tunnel junction cell 10 can be switched between the parallel state (i.e., low resistance state or “0” data state) and anti-parallel state (i.e., high resistance state or “1” data state).

The illustrative spin-transfer torque magnetic tunnel junction cell 10 may be used to construct a memory device where a data bit is stored in the magnetic tunnel junction cell by changing the relative magnetization state of free layer 12 with respect to pinned layer 14. The stored data bit can be read out by measuring the resistance of cell 10 which changes with the magnetization direction of free layer 12 relative to pinned layer 14. Free layer 12 exhibits thermal stability against random fluctuations so that the orientation of free layer 12 is changed only when it is controlled to make such a change. This thermal stability can be achieved via the magnetic anisotropy using different methods, e.g., varying the bit size, shape, and crystalline anisotropy. Additional anisotropy can be obtained through magnetic coupling to other magnetic layers either through exchange or magnetic fields. Generally, the anisotropy causes a soft and hard axis to form in thin magnetic layers. The hard and soft axes are defined by the magnitude of the external energy, usually in the form of a magnetic field, needed to fully rotate (saturate) the direction of the magnetization in that direction, with the hard axis requiring a higher saturation magnetic field.

In the memory units of this disclosure, magnetic tunnel junction 10 is configured to be switched from a first resistance state to a second resistance state (e.g., from the anti-parallel or high resistance state to the parallel or low resistance state; or, from the parallel or low resistance state to the anti-parallel or high resistance state) and not switched back to the first state during operation of the memory unit. Magnetic tunnel junction cell 10 is pre-programmed to the first resistance state by an external magnetic field. The external magnetic field may be provided, for example, by a horseshoe magnetic in close proximity to magnetic tunnel junction 10. The pre-programmed cell 10 is then written once (i.e., switched to the second resistance state, or left in the first resistance state) by a voltage, and read by a voltage less than the writing voltage.

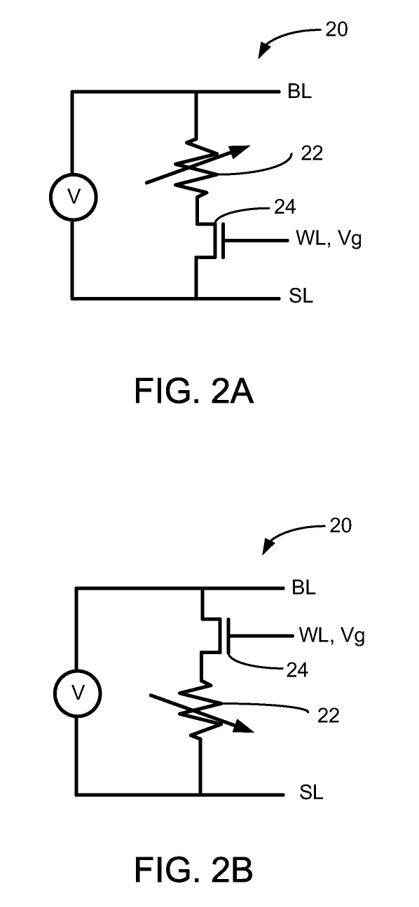

FIGS. 2A and 2B are schematic circuit diagrams of a memory unit 20 that includes a magnetic tunnel junction cell 22 electrically coupled to a bit line BL and a word line WL. Magnetic tunnel junction cell 22, generally described above as magnetic tunnel junction cell 10, is configured to switch from the first resistance state to the second resistance state by passing a voltage through magnetic tunnel junction cell 22. In FIG. 2A, a transistor 24 (e.g., an NMOS transistor) is electrically between magnetic tunnel junction cell 22 and source line SL. Also present is a word line WL connected to the gate of transistor 24 and a bit line BL. In other embodiments, transistor 24 is electrically coupled between magnetic tunnel junction cell 22 and bit line BL, as illustrated in FIG. 2B. Also present is a word line WL connected to the gate of transistor 24 and a source line SL. In both embodiments, a voltage source V provides voltage across magnetic tunnel junction cell 22 to write the second resistance state.

In conventional spin torque memory units, two directional current switching is required to switch the resistance of the magnetic tunnel junction cell back and forth between first and second (e.g., high and low) resistance multiple times. As the cell is switched from its high resistance state to low resistance state, a significant voltage drop across the resistor pulls up the source bias of the transistor and therefore limits the driving capability of the transistor. In other terms, when the resistance across the magnetic tunnel junction is large, the source bias is large due to the I*R effect. In turn this reduces the voltage across word line WL and source line SL and across bit line BL and source line SL. Because of this, a very wide transistor is needed to provide sufficient driving current to switch the magnetic tunnel junction cell. A wide transistor greatly limits the density of the memory.

In accordance with this disclosure, for memory unit 20, which is one time programmable (OTP) memory and switchable only from the first resistance state (e.g., the high resistance state) to the second resistance state (e.g., the low resistance state), one only needs to worry about injecting current in the “forward” direction, to switch the resistance state from high to low or from low to high. This is in contrast to previous spin torque memory units which are switchable from a first resistance state (e.g., the high resistance state) to a second resistance state (e.g., the low resistance state) by passage of current in a first direction and then back to the first resistance state by passage of current in a second, opposite direction.

The initialization or pre-programming of magnetic tunnel junction cell 22 can be achieved, for example, by using an external magnetic field generated by a strong magnet, such as a horseshoe magnet, to initialize the magnetic tunnel junction cell to the first (e.g., high) state. By doing so, a much smaller transistor can be used since source bias loading is greatly reduced. Therefore, a much higher density array can be achieved. This design, does however, require three contact terminals: bit line BL, word line WL, and a source contact SL.

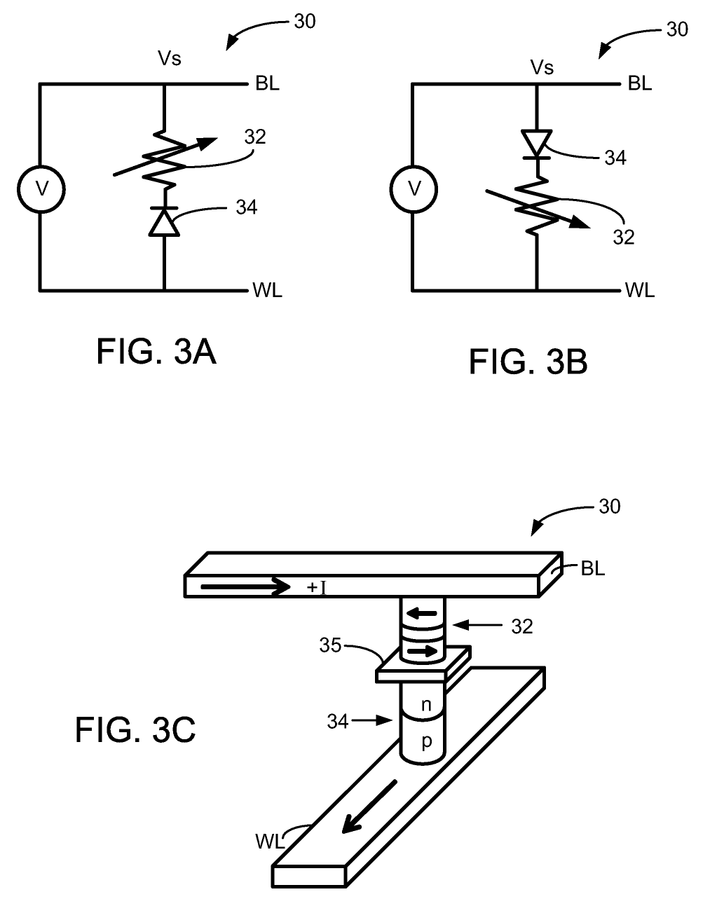

Another embodiment of a memory unit that includes a magnetic tunnel junction cell and is configured to switch only from a first resistance state to a second resistance state, and not back, includes a device that has a rectifying switching characteristic, such as a diode or other non-ohmic device, rather than a transistor. FIGS. 3A and 3B are schematic circuit diagrams of a memory unit 30 that includes a magnetic tunnel junction cell 32 electrically coupled to a bit line BL and a word line WL. Magnetic tunnel junction cell 32, generally described above as magnetic tunnel junction cell 10, is configured to switch from a first (e.g., high) resistance state and a second (e.g., low) resistance state by passing a voltage through magnetic tunnel junction cell 32. In FIG. 3A, a diode 34 or other non-ohmic device is electrically between the magnetic tunnel junction cell 32 and word line WL. In other embodiments, diode 34 is electrically coupled between magnetic tunnel junction cell 32 and bit line BL, as illustrated in FIG. 3B. Diode 34 or other non-ohmic device allows an electric current to pass in one direction (referred to herein as the forward biased condition or “forward bias”) and to block electrical current it in the opposite direction (the reverse biased condition or “reverse bias”). Thus, the diode can be thought of as an electronic version of a check valve. A voltage source V provides the voltage across magnetic tunnel junction cell 32 to write the second resistance state.

FIG. 3C is a perspective view schematic diagram of an illustrative memory unit 30. Memory unit 30 includes magnetic tunnel junction cell 32 electrically coupled to a bit line BL and a word line WL. In the illustrated embodiment, bit line BL and word line WL are orthogonal to each other and form a cross-point where diode 34 and cell 32 are located therebetween. Magnetic tunnel junction cell 32 is programmed in the high resistance state, switchable to only the low resistance state by passing a voltage through magnetic tunnel junction cell 32. Diode 34 (illustrated as a p-n junction diode, for example only) is electrically between magnetic tunnel junction cell 32 and word line WL. In other embodiments, diode 34 is electrically between magnetic tunnel junction cell 32 and bit line BL, as illustrated in FIG. 3B. A connecting layer 35 is illustrated between magnetic tunnel junction cell 32 and diode 34. Connecting layer 35 can be an electrically conducting and nonmagnetic layer. A voltage source (not shown) provides the voltage across magnetic tunnel junction cell 32 to write to the low resistance state.

In accordance with this disclosure, for memory unit 30, which is one time programmable (OTP) memory and switchable only from a first resistance state to a second resistance state (e.g., from the high resistance state to the low resistance state), pre-programming or initialization of magnetic tunnel junction cell 32 to the first (e.g. high) state can be achieved by using an external strong magnet. Then, in use, programming of cell 32 is achieved by passing a current through diode 34 and cell 32, in the forward direction, to switch the cell's resistance to the second (e.g., low) state. In the embodiment illustrated in FIG. 3C, current passes through magnetic tunnel junction cell 32 and then through diode 34.

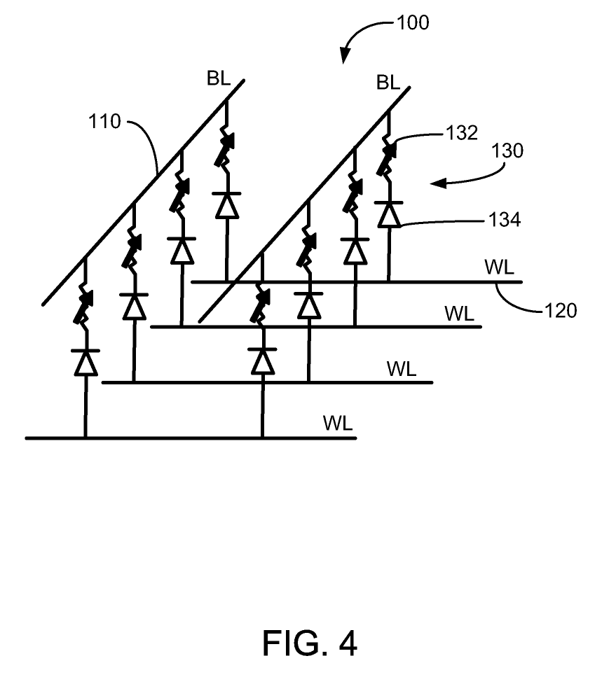

FIG. 4 is a schematic circuit diagram of an illustrative memory array 100. A plurality of memory units 130, such as memory units 30 (not shown in FIG. 4), can be arranged in an array to form memory array 100. Each memory unit 130 includes a magnetic tunnel junction cell 132 (generally described above as magnetic tunnel junction cell 32) and a non-ohmic device such as a diode 134 (generally described above as diode 34). Memory array 100 includes a number of parallel conductive bit lines 110 and a number of parallel conductive word lines 120 that are generally orthogonal to bit lines 110. Word lines 120 and bit lines 110 form a cross-point array where a memory unit 130 is positioned at each cross-point. For memory arrays utilizing memory units that include a magnetic tunnel junction cell and a transistor, three lines would be present, bit lines, word lines, and source lines. Memory unit 150 and memory array 100 can be formed using conventional semiconductor fabrication techniques.

Because the drive strength of a diode is typically much greater than an NMOS transistor, the size of the diode can be made very small in the unit memory cell. Therefore, diode-based OTP memory arrays can have an extremely high density, higher than transistor-based OTP memory arrays. Since a diode is only a two terminal device, any array configuration can also be very simple. By using a diode to form the memory unit, the size of the memory unit is small, usually less than 5 F, where F is the minimum feature size of the magnetic tunnel junction cell and of the diode. In some embodiments, the memory unit size is less than 4 F. The simplicity of a diode-based unit reduces the process complexity and saves processing cost.

Pre-programming of memory unit 130 and cell 132 can be achieved by bringing a strong magnet, such as a horseshoe magnet, in close proximity to array 100. The magnetic field from the magnet is sufficiently strong (for example, at least 100 Oe, or, in some embodiments, at least about 500 Oe) to orient the ferromagnetic layers of cell 132 in the desired orientation, either (1) anti-parallel, providing cell 132 in the high resistance state, or (2) parallel, providing cell 132 in the low resistance state. Programming of memory unit 130 and cell 132, by switching the resistance state, can be achieved by keeping the corresponding word line 120 low at Vₛₛ and driving the corresponding bit line 110 to V_{dd}. Word lines 120 for other rows are driven to V_{dd} to avoid disturbance to the un-selected units 130. Reading is achieved by forward biasing the selected cell 132 and sensing the resistance across cell 132. In order to avoid affecting the resistance state of cell 32, the voltage to read cell 132 is less than the voltage to switch cell 132 to the second resistance state.

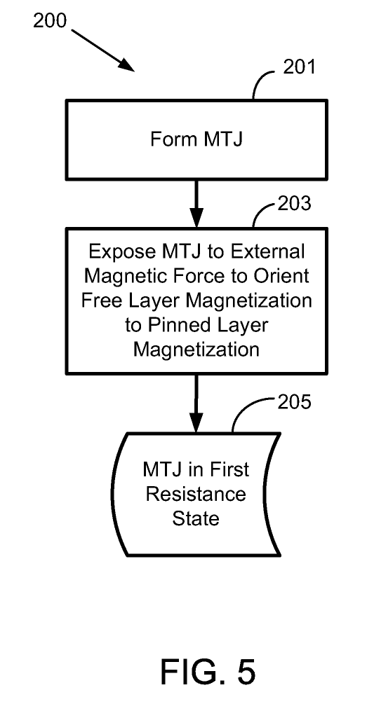

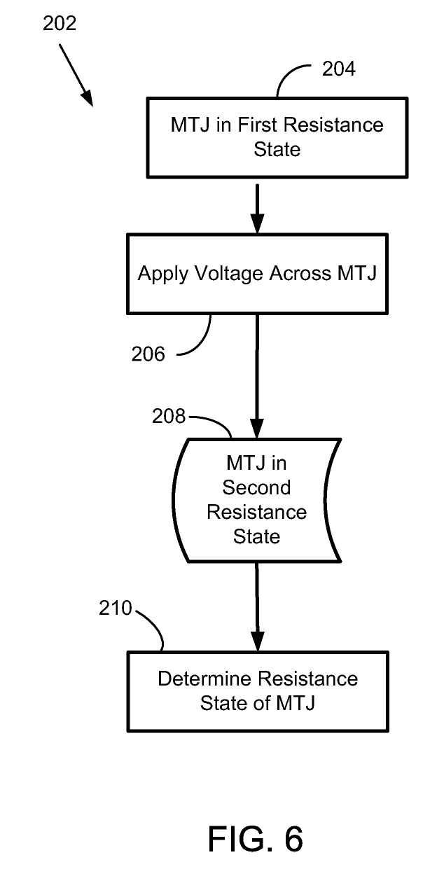

FIG. 5 is a flow chart illustrating a method for pre-programming a magnetic tunnel junction cell to the first resistance state, and FIG. 6 is a flowchart illustrating a method of switching an already pre-programmed magnetic tunnel junction cell from the first resistance state to a second resistance state.

Method 200 for pre-programming includes step 201 of forming a magnetic tunnel junction cell, the cell being electrically connected to a transistor or a diode. The magnetic tunnel junction cell can made using well-known thin film techniques (e.g., chemical vapor deposition (CVD), physical vapor deposition (PVD), atomic layer deposition (ALD), photolithography, or other thin film processing techniques. The magnetization orientation of the pinned layer may be set immediately after forming the pinned layer or after forming subsequent layer(s). Step 203 includes exposing the magnetic tunnel junction cell to an external magnetic field (in some embodiments, at least about 100 Oe, or, in some embodiments, at least about 500 Oe) to orient the magnetization orientation of the free layer in the desired orientation to the pinned layer, either parallel or anti-parallel. This sets the magnetic tunnel junction cell in a first resistance state, in step 205.

Method 202 provides programming or switching the resistance of a magnetic tunnel junction cell. Method 202 includes a step 204 of having a magnetic tunnel junction cell in its first resistance state, either anti-parallel or parallel. Step 206 provides for switching the MTJ data cell from the first resistance state to a second resistance state by applying a forward bias voltage through the magnetic tunnel junction cell; in some embodiments, the forward bias is dictated by the present of a diode. To switch the cell to the second resistance, a current of less than about 500 microAmps is needed; in some embodiments, particularly those having a diode with the magnetic tunnel junction cell, a current of less that about 200 microAmps, or less than about 100 microAmps, will switch the state. The resulting magnetic tunnel junction cell has a second resistance, in step 208.

To read the state of the magnetic tunnel junction cell, in step 210, the resistance of the cell is measured to determine if the cell is in the low resistance state (e.g., parallel or “0”) or the high resistance state (e.g., anti-parallel or “1”). This reading can be done by using a current that is less than the current needed to switch the cell from the first resistance state to the second resistance state, to avoid switching the state during the reading process. Step 210 may be repeated as desired (e.g., once or multiple times), for example, to confirm the resistance state. Subsequent readings will provide the same resistance state as the first reading.

Although the memory units of this disclosure have been described as one time programmable memory (OTP), a memory unit may be re-programmed back to the first resistance state by exposing the magnetic tunnel junction cell to a strong external magnetic field. This re-programming would not be within the ordinary scope of use of the memory unit, but rather, would be an occasional (e.g., monthly, yearly) occurrence done to reconfigure the memory unit and the memory array of which it is a part.

Thus, embodiments of the HIGH DENSITY RECONFIGURABLE SPIN TORQUE NON-VOLATILE MEMORY are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A one time programmable memory unit comprising:
a magnetic tunnel junction cell electrically coupled to a bit line and a word line, the magnetic tunnel junction cell is configured to switch only from a first resistance state to a second resistance state by passing a voltage across the magnetic tunnel junction cell;
a non-ohmic device electrically coupled between the magnetic tunnel junction cell and the word line or bit line; and
a voltage source providing the voltage across the magnetic tunnel junction cell that writes the second resistance state.

2. The memory unit of claim 1, wherein the non-ohmic device is a diode.

3. The memory unit of claim 1, wherein the magnetic tunnel junction cell comprises an oxide barrier layer between a ferromagnetic free layer and a ferromagnetic pinned layer.

4. The memory unit of claim 1, wherein the first resistance state is a high resistance state and the second resistance state is a low resistance state.

5. The memory unit of claim 1, wherein the first resistance state is a low resistance state and the second resistance state is a high resistance state.

6. A method of pre-programming a magnetic tunnel junction cell, the method comprising:
providing a magnetic tunnel junction cell having an oxide barrier layer between a ferromagnetic free layer and a ferromagnetic pinned layer, each of the free layer and the pinned layer having a magnetization orientation;
orienting the free layer magnetization orientation in relation to the pinned layer magnetization orientation by exposing the magnetic tunnel junction cell to an external magnet.

7. The method of claim 6, wherein exposing the magnetic tunnel junction cell to an external magnet comprises exposing the magnetic tunnel junction cell to a horseshoe magnet.

8. The method of claim 6, wherein exposing the magnetic tunnel junction cell to an external magnet comprises exposing the magnetic tunnel junction cell to at least 100 Oe.

9. The method of claim 6, wherein exposing the magnetic tunnel junction cell to an external magnet comprises exposing the magnetic tunnel junction cell to at least 500 Oe.

10. The method of claim 6, wherein orienting the free layer magnetization orientation in relation to the pinned layer magnetization orientation comprises orienting the free layer magnetization orientation anti-parallel to the pinned layer magnetization orientation.

11. The method of claim 6, wherein orienting the free layer magnetization orientation in relation to the pinned layer magnetization orientation comprises orienting the free layer magnetization orientation parallel to the pinned layer magnetization orientation.

12. A method comprising:
providing a one time programmable memory unit including magnetic tunnel junction cell having an oxide barrier layer between a ferromagnetic free layer and a ferromagnetic pinned layer, each of the free layer and the pinned layer having a magnetization orientation, with the magnetization orientations producing a first resistance state; and
writing to the one time programmable memory unit by switching the magnetic tunnel junction cell from the first resistance state to a second resistance state by passing a forward bias voltage through the magnetic tunnel junction cell, the voltage providing a current of no more than 500 microAmps.

13. The method of claim 12, wherein the switching is done by a current of no more than 200 microAmps.

14. The method of claim 12, wherein the switching is done by a current of no more than 100 microAmps.

15. The method of claim 12 wherein:
providing a one time programmable memory unit comprises providing a one time programmable memory unit with the magnetization orientations of the magnetic tunnel junction cell producing a high resistance state; and
writing to the one time programmable memory unit comprises writing to the one time programmable memory unity by switching the magnetic tunnel junction cell from the high resistance state to a low resistance state.

16. The method of claim 12 wherein:
providing a one time programmable memory unit comprises providing a one time programmable memory unit with the magnetization orientations of the magnetic tunnel junction cell producing a low resistance state; and
writing to the one time programmable memory unit comprises writing to the one time programmable memory unity by switching the magnetic tunnel junction cell from the low resistance state to a high resistance state.

17. The method of claim 12 further comprising passing the forward bias voltage through a transistor.

18. The method of claim 12 further comprising passing the forward bias voltage through a diode.

19. The method of claim 12 further comprising reading the one time programmable memory unit.

20. The method of claim 19 further comprising again reading the one time programmable memory unit.
